(19) United States
(12) Patent Application Publication
(10) Pub. No.: US 2012/0326332 A1
(43) Pub. Date: Dec. 27, 2012

(54) SEMICONDUCTOR DEVICE WITH ENCAPSULATED ELECTRICAL CONNECTION ELEMENTS AND FABRICATION PROCESS THEREOF

(75) Inventor: Patrick Laurent, Tullins (FR)

(73) Assignee: STMICROELECTRONICS (GRENOBLE 2) SAS, Grenoble (FR)

(21) Appl. No.: 13/524,073

(22) Filed: Jun. 15, 2012

(30) Foreign Application Priority Data
Jun. 21, 2011 (FR) 1155433

(51) Int. Cl. H01L 25/065; H01L 23/50; H01L 21/98

(52) U.S. Cl. 257/777; 438/127; 257/734; 257/E21.705; 257/E23.079; 257/E25.013

(57) ABSTRACT

An integrated-circuit chip and external electrical connection elements are arranged on a first side of a substrate to form an assembly that is placed within a mold. The mold includes first and second opposed planar faces with a molding film made of a deformable material on the first planar face. The molding film is pressed against end faces of the external electrical connection elements. Encapsulating material then fills the mold cavity producing a semiconductor device that, when removed from the mold, includes electrical connection elements that are peripherally coated by the encapsulating material and have exposed end faces. An additional semiconductor device may be mounted over and in electrical connection with the electrical connection elements through the exposed end faces.

### PRIORITY CLAIM

This application claims priority from French Application for Patent No. 1155433 filed Jun. 21, 2011, the disclosure of which is hereby incorporated by reference.

### TECHNICAL FIELD

The present invention relates to the field of semiconductor devices.

### BACKGROUND

Semiconductor devices comprising a substrate die, an integrated-circuit chip mounted on one side of this substrate die, and a block encapsulating the integrated-circuit chip, covering this side, are known. To make external electrical connections to the integrated-circuit-chip side, holes are provided in the encapsulating block, then solder droplets are deposited in these holes. This procedure has the following drawbacks: it takes a long time to produce the holes using a laser; the holes must be cleaned so as to prevent poor electrical contact between the solder droplets and the tracks or pads of the substrate die; and, when a small pitch between holes is desired, and when the holes are very small, applying small solder droplets consequently poses real difficulties. All this results in semiconductor devices that are expensive.

There is a need in the art to avoid the above drawbacks.

### SUMMARY

A process is provided for fabricating a semiconductor device, which comprises: producing a subassembly comprising a substrate die having first and second opposed sides, at least one integrated-circuit chip and external electrical connection elements arranged on the first side of the substrate; placing the subassembly in a cavity of a mold comprising first and second opposed faces and equipped with a molding film made of a deformable material against its first face, in a position such that the second side of the substrate die lies against the second face of the cavity and such that said electrical connection elements make contact with said molding film, in respective bearing regions; injecting or thermally compressing an encapsulating material into the cavity of the mold; and extracting the semiconductor device obtained, the electrical connection elements of this semiconductor device being peripherally coated by the encapsulating material and having exposed end faces corresponding to said bearing regions.

The material forming said molding film may be chosen such that said electrical connection elements penetrate into this film.

The process may comprise: placing the subassembly in the cavity of the mold in a position such that the integrated-circuit chip is at a certain distance from the molding film.

The process may comprise: placing the subassembly in the cavity of the mold in a position such that the integrated-circuit chip bears on the molding film.

A semiconductor device is also provided that comprises: a substrate die having first and second opposed sides, at least one integrated-circuit chip and external electrical connection elements arranged on the first side of the substrate die; and an encapsulating block coating at least the periphery of said integrated-circuit chip and coating the periphery of the electrical connection elements such that the latter have exposed end faces.

The encapsulating block may have one side parallel to the first side of the substrate die.

The substrate die may comprise a network for electrically connecting one side to the other, selectively connected to said integrated-circuit chip and to said external electrical connection elements.

A stack is also provided which comprises the aforementioned semiconductor device, and which comprises another semiconductor device and other electrical connection elements connected to said external electrical connection elements.

A mold is also provided for fabricating a semiconductor device, comprising a cavity for receiving a substrate die having first and second opposed faces and equipped with at least one integrated-circuit chip and external electrical connection elements on the first side, and in which one face of the cavity, intended to be located a certain distance from the first side of the substrate, is covered, at least partially, with a molding film made of a deformable material, at least in the region of the external electrical connection elements.

The cavity of the mold may have a face intended to support said substrate die.

### BRIEF DESCRIPTION OF THE DRAWINGS

Semiconductor devices and fabrication methods will now be described via non-limiting example, illustrated schematically by the following drawings in which:

FIG. 1 shows a cross section of a semiconductor device;

FIGS. 2 to 5 show, in cross section, fabrication steps for the semiconductor device of FIG. 1; and

FIG. 6 shows a cross section of a stack comprising the semiconductor device of FIG. 1; and

FIGS. 7 and 8 show, in cross section, fabrication steps for another semiconductor device.

### DETAILED DESCRIPTION OF THE DRAWINGS

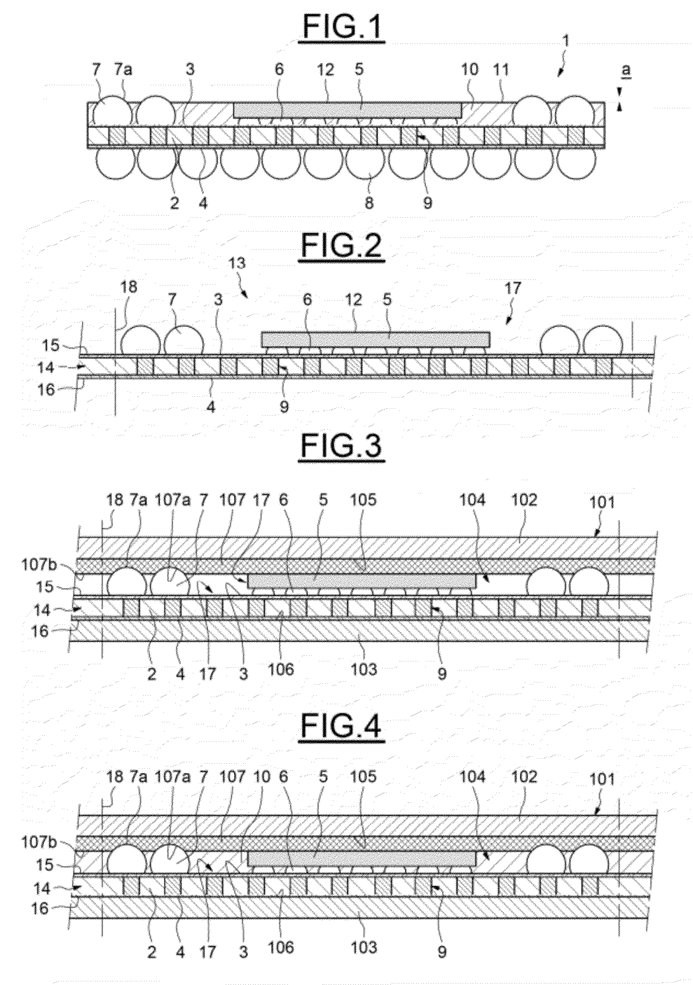

As illustrated in FIG. 1, a semiconductor device 1 comprises a substrate die 2 that has first and second opposed sides 3 and 4, an integrated-circuit chip 5 mounted on the first side 3 by means of intermediate electrical connection elements 6, first external electrical connection elements 7 placed on the first side 3, around and at a certain distance from the periphery of the integrated-circuit chip 5, and second external electrical connection elements 8 placed on the second side 4. For example, these electrical connection elements may consist of metal bumps or even columns.

The substrate die 2 comprises an electrically insulating material and an electrical connection network 9 allowing electrical connections to be made from one side to the other and on sides 3 and 4, so as to selectively connect the integrated-circuit chip 5, the electrical connection elements 7 and the electrical connection elements 8. The substrate die 2 may be a single layer or multilayer.

The semiconductor device 1 furthermore comprises an encapsulating block 10, made of an electrically insulating material, which is formed on the first side 3 of the substrate die 2, which coats at least the periphery of the integrated-circuit chip 5 and which coats only the periphery of the external electrical connection elements 7, such that these external electrical connection elements 7, partially embedded in the encapsulating block 10, have exposed end faces 7a. The top of the exposed end face 7a may protrude a distance “a” from the external side 11 of the encapsulating block 10.

According to this example, the external side 11 of the encapsulating block 10 and the external side 12, opposite the intermediate electrical connection elements 6, of the integrated-circuit chip 5 lie in the same plane, or approximately in the same plane, parallel to the first side 3 of the substrate die 2, such that the external side 12 of the integrated-circuit chip 5 is exposed.

According to one variant embodiment, the ratio of the height of the first external electrical connection elements 7 to the thickness of the encapsulating block 10, measured from the first surface 3 of the substrate die 2, may lie between 1.1 and 1.6.

The semiconductor device 1 may be produced by wafer-scale fabrication which will now be described.

As illustrated in FIG. 2, an assembly 13 is provided comprising a substrate wafer 14 having first and second sides 15 and 16, and comprising a plurality of subassemblies 17 of semiconductor devices 1 to be produced, formed in adjacent locations 18 on the substrate wafer 14.

Each subassembly 17 comprises, in each location 18, a portion of the substrate wafer 14, corresponding to a substrate die 2, and, on the first side 15 of this substrate wafer 14, an integrated-circuit chip 5 mounted via electrical connection elements 6 and first external electrical connection elements 7.

Each subassembly 17 is such that the height of the first external electrical connection elements 7, measured from the first side 15 of the substrate wafer 14, including the first sides of the substrate dies 2, is greater than the distance between the external side 12 of the integrated-circuit chip 5 and the first side 15 of the substrate wafer 14.

As illustrated in FIG. 3, a mold 101 is provided comprising two opposed mold parts 102 and 103 bounding between them a cavity 104 and having first and second opposed parallel planar faces 105 and 106, the first face 105 being equipped with a molding film 107 made of a deformable material and having a planar face 107b exposed in the cavity 104 and parallel to the second face 106. The molding film 107 may be made of a polymer, for example polyethylene or polyurethane, and may be bonded to the face 105 of the cavity 104 by lamination.

The assembly 13 is placed in the cavity 104 of the mold 101 in a position such that, after the mold 101 has been closed, the second side 16 of the substrate wafer 14, including the second sides 4 of the substrate dies 2, is against the second face 106 of the mold 101 and the external side 12 of each integrated-circuit chip 5 makes contact with or bears against the molding film 107 or slightly penetrates the latter, whereas the first external electrical connection elements 7 make contact with the molding film 107 only in bearing regions 107a corresponding to the exposed faces 7a to be obtained. These bearing regions 107a result from penetration of the end parts of the first external electrical connection elements 7 into the planar face 107b of the molding film 107 turned towards the cavity 104.

The ratio of the penetration depth of the electrical connection elements 7 in the molding film 107 to the thickness of this molding film 107 may lie between 0.1 and 0.5.

Next, as illustrated in FIG. 4, an encapsulating material, for example an epoxy resin, is injected into the cavity 104 so as to form a wafer-scale encapsulating block 19 forming an encapsulating block 10 in each location 18.

After demolding, as illustrated in FIG. 5, a second assembly 20 is obtained comprising the assembly 13 and the wafer-scale encapsulating block 19. Next, in each location 18, second external electrical connection elements 8 are produced on the second side 16 of the substrate wafer 14, including the second sides 4.

Thus, encapsulated integrated-circuit chips and vias through the encapsulating block are obtained in a single operation.

According to one variant embodiment, it is then possible to singulate the various semiconductor devices 1 by dicing the second assembly 20 along the edges of the locations 18.

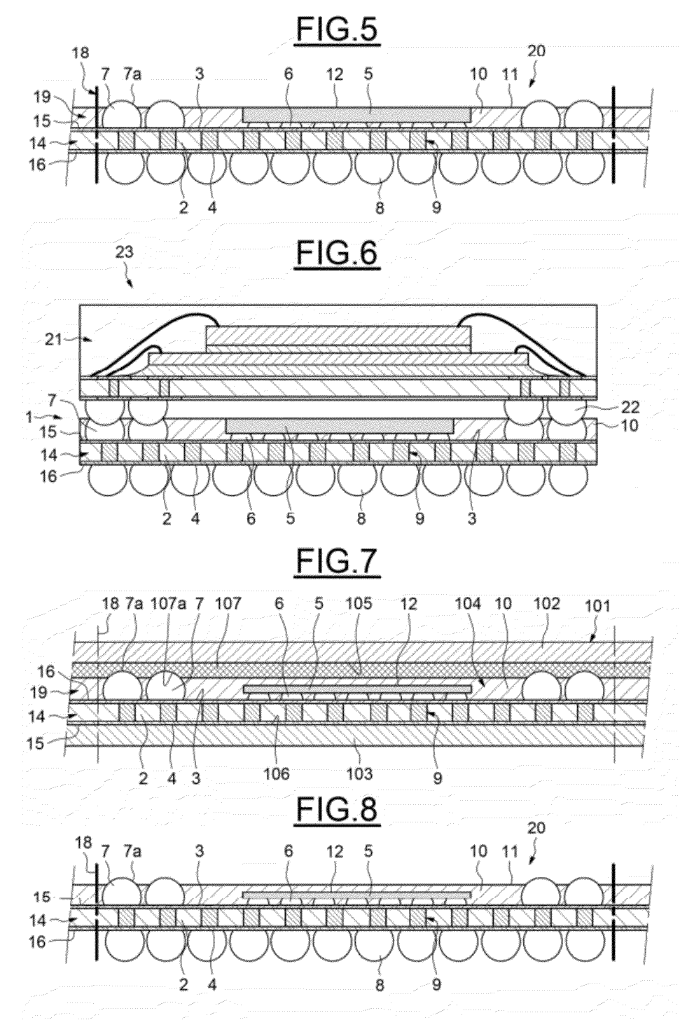

According to another variant embodiment, illustrated in FIG. 6, another semiconductor device 21 may be mounted above the semiconductor device 1, on the side of the first electrical connection elements 7, for example via electrical connection elements 22 placed on the first electrical connection elements 7 of the semiconductor device 1 so as to make an electrical connection between the other semiconductor device 21 and the electrical connection network 9 of the semiconductor device 1. A stack 23 is thus obtained. This stack 23 may, for example, be produced after the semiconductor device 1 has been mounted on a printed circuit board (not shown) via the second electrical connection elements 8.

According to one variant fabrication process illustrated in FIG. 7, an assembly 13 may be placed in the cavity 104 of a mold 101 in a position such that the external side 12 of the integrated-circuit chip 5 is at a certain distance from a molding film 107.

In this case, as illustrated in FIG. 8, the assembly 13 obtained after a coating material has been injected then comprises a wafer-scale encapsulating block 19 that covers the external side 12 of the integrated-circuit chip 5, the latter possibly having been thinned.

The present invention is not limited to the examples described above. Many other variant embodiments are possible without departing from the scope defined in the appended claims.

What is claimed is:

1. A process for fabricating a semiconductor device, comprising:
producing a subassembly comprising a substrate die having first and second opposed sides, at least one integrated-circuit chip and external electrical connection elements arranged on the first side of the substrate;
placing the subassembly in a cavity of a mold comprising first and second opposed planar faces and equipped with a molding film against its first face, said molding film made of a deformable material and having a planar face exposed in the cavity, in a position such that the second side of the substrate die lies against the second face of the cavity, such that the substrate die is in contact with the molding film and such that said electrical connection elements penetrate in said molding film, through the previously planar face thereof, and are in contact with respective bearing regions thereof;
injecting or thermally compressing an encapsulating material into the cavity of the mold; and
extracting the semiconductor device obtained, the electrical connection elements of this semiconductor device being peripherally coated by the encapsulating material and having exposed end faces corresponding to said bearing regions.

2. The Process according to claim 1, wherein a top surface of the at least one integrated-circuit chip bears against the molding film.

3. The Process according to claim 1, wherein a top surface of the at least one integrated-circuit chip is separated by a distance from the molding film, wherein injecting or thermally compressing comprises injecting or thermally compressing the encapsulating material to fill said distance.

4. A semiconductor device comprising:
a substrate die having first and second opposed sides,
at least one integrated-circuit chip and external electrical connection elements arranged on the first side of the substrate die, and
an encapsulating block coating at least the periphery of said integrated-circuit chip and coating the periphery of the electrical connection elements such that the electrical connection elements have exposed end faces,
said encapsulating block and circuit chip having external faces extending in a common plane which is parallel to the first side of the substrate die.

5. The device according to claim 4, wherein the substrate die comprises a network configured to electrically connect one side to the other, selectively connected to said integrated-circuit chip and to said external electrical connection elements.

6. A device, comprising:
a first semiconductor device, comprising:
a substrate die having first and second opposed sides,
at least one integrated-circuit chip and external electrical connection elements arranged on the first side of the substrate die, and
an encapsulating block coating at least the periphery of said integrated-circuit chip and coating the periphery of the electrical connection elements such that the electrical connection elements have exposed end faces, and
a second semiconductor device mounted above the first semiconductor device and electrically connection to the first semiconductor device through the exposed end faces of the external electrical connection elements.

7. The device of claim 6, wherein said encapsulating block and circuit chip having external faces extending in a common plane which is parallel to the first side of the substrate die.

8. A method, comprising:
attaching at least one integrated-circuit chip to a first side of a substrate;
attaching a plurality of external electrical connection balls to the first side of the substrate;
placing the substrate with attached integrated-circuit chip and external electrical connection balls in a mold, said mold comprising first and second opposed planar faces and including a molding film on the first planar face, said molding film made of a deformable material;
pressing the molding film into the plurality of external electrical connection balls on the first side of the substrate such that the deformable material covers an end face of each external electrical connection ball and defines a cavity on a side of each external electrical connection ball;
filling the cavity of the mold with an encapsulating material;
removing the mold to produce a semiconductor device wherein the end faces of the external electrical connection balls are exposed and sides are covered by the encapsulating material.

9. The method of claim 8, wherein a top surface of the at least one integrated-circuit chip bears against the molding film.

10. The method of claim 8, wherein a top surface of the at least one integrated-circuit chip is separated by a distance from the molding film, wherein filling comprises filling said distance with the encapsulating material.
